(19) United States
(12) Patent Application Publication
(10) Pub. No.: US 2024/0164091 A1
(43) Pub. Date: May 16, 2024

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Choasub Kim, Suwon-si (KR); Chung Jin Kim, Suwon-si (KR); Hyungang Kim, Suwon-si (KR); Soyeon Seok, Suwon-si (KR); Jungho Lee, Suwon-si (KR); Yunkyu Jung, Suwon-si (KR)

(21) Appl. No.: 18/322,842

(22) Filed: May 24, 2023

(30) Foreign Application Priority Data
Nov. 14, 2022 (KR) 10-2022-0151860

(51) Int. Cl. H10B 41/27; H01L 23/528; H01L 25/065; H10B 41/10; H10B 41/35; H10B 43/10; H10B 43/27; H10B 43/35; H10B 80/00

(52) U.S. Cl. CPC H10B 41/27; H01L 23/5283; H01L 25/0652; H10B 41/10; H10B 41/35; H10B 43/10; H10B 43/27; H10B 43/35; H10B 80/00; H01L 2225/06506; H01L 2225/06524

(57) ABSTRACT

Disclosed are semiconductor devices, electronic systems including the same, and methods of fabricating the same. The semiconductor device comprises a source structure that includes a support source layer, a gate stack structure on the support source layer, a memory channel structure that penetrates through the gate stack structure and the support source layer, and a separation structure that penetrates through the gate stack structure and the support source layer. The support source layer includes a first source part through which the memory channel structure penetrates, and a second source part through which the separation structure penetrates. A top surface of the first source part is at a level lower than that of a top surface of the second source part.

### CROSS-REFERENCE TO RELATED APPLICATION

This U.S. nonprovisional application is based on and claims priority under 35 U.S.C § 119 to Korean Patent Application No. 10-2022-0151860 filed on Nov. 14, 2022 in the Korean Intellectual Property Office, the disclosure of which is hereby incorporated by reference in its entirety.

### BACKGROUND

The present inventive concepts relate to a semiconductor device and an electronic system including the same, and more particularly, to a semiconductor device including a source structure and an electronic system including the same.

A semiconductor device attracts attention as an essential element in electronic industry because of its properties such as compactness, multi-functionality, and/or low manufacturing cost. Semiconductor devices may encompass semiconductor memory devices storing logic data, semiconductor logic devices processing operations of logic data, and hybrid semiconductor devices having both memory and logic elements.

Recently, high speed and low power consumption requirements of electronic products require that semiconductor devices embedded in the electronic products should have high operating speed and/or lower operating voltage. However, an increase in integration of semiconductor devices may cause a reduction in electrical properties and production yield of semiconductor devices. Therefore, many studies have been conducted to increase electrical properties and production yield of semiconductor devices.

### SUMMARY

Some embodiments of the present inventive concepts provide a semiconductor device with increased reliability and improved electrical properties and an electronic system including the same.

According to some embodiments of the present inventive concepts, a semiconductor device may comprise: a source structure that includes a support source layer; a gate stack structure on the support source layer; a memory channel structure that penetrates through the gate stack structure and the support source layer; and a separation structure that penetrates through the gate stack structure and the support source layer. The support source layer may include: a first source part through which the memory channel structure penetrates; and a second source part through which the separation structure penetrates. A top surface of the first source part may be at a level lower than a level of a top surface of the second source part.

According to some embodiments of the present inventive concepts, a semiconductor device may comprise: a source structure that includes a support source layer; a gate stack structure that includes a connection dielectric pattern in contact with the support source layer; a memory channel structure that penetrates through the gate stack structure and the support source layer; and a separation structure that penetrates through the gate stack structure and the support source layer. The support source layer may include: a first source part through which the memory channel structure penetrates; and a second source part through which the separation structure penetrates. The connection dielectric pattern may include: a first dielectric part through which the memory channel structure penetrates; and a second dielectric part through which the separation structure penetrates. The first source part may include a first contact surface in contact with the first dielectric part. The second source part may include a second contact surface in contact with the second dielectric part. A level of the first contact surface may be different from a level of the second contact surface.

According to some embodiments of the present inventive concepts, an electronic system may comprise: a main board; a semiconductor device on the main board; and a controller on the main board and electrically connected to the semiconductor device. The semiconductor device may include: a source structure that includes a support source layer; a gate stack structure that includes a connection dielectric pattern in contact with the support source layer; a memory channel structure that penetrates through the gate stack structure and the support source layer; and a separation structure that penetrates through the gate stack structure and the support source layer. The support source layer may include: a first source part through which the memory channel structure penetrates; and a second source part through which the separation structure penetrates. The connection dielectric pattern may include: a first dielectric part in contact with the first source part; and a second dielectric part in contact with the second source part. A thickness of the first source part may be less than a thickness of the second source part. A thickness of the first dielectric part may be greater than a thickness of the second dielectric part.

According to some embodiments of the present inventive concepts, a method of fabricating a semiconductor device may comprise: forming a base source layer; forming a dummy source structure on the base source layer; forming a support source layer on the dummy source structure; forming on the support source layer a mask pattern that exposes a portion of a top surface of the support source layer; using the mask pattern as an etching mask to etch the support source layer; forming dielectric layers and sacrificial layers on the etched support source layer; and forming a memory channel structure that penetrates through the dielectric layers, the sacrificial layers, and the support source layer.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1A illustrates a simplified block diagram showing an electronic system including a semiconductor device according to some embodiments;

FIG. 1B illustrates a simplified perspective view showing an electronic system including a semiconductor device according to some embodiments;

FIGS. 1C and 1D illustrate simplified cross-sectional views showing a semiconductor package according to some embodiments;

FIG. 2A illustrates a plan view showing a semiconductor device according to some embodiments;

FIG. 2B illustrates a cross-sectional view taken along lines A-A′ and B-B′ of FIG. 2A;

FIG. 2C illustrates an enlarged view showing section C of FIG. 2B;

FIG. 2D illustrates an enlarged view showing section D of FIG. 2B;

FIGS. 3A, 3B, 3C, and 3D illustrate cross-sectional views showing intermediate processes of an example method of fabricating the semiconductor device depicted in FIGS. 2A, 2B, 2C, and 2D, according to one or more embodiments;

FIG. 4 illustrates a cross-sectional view showing a semiconductor device according to some embodiments;

FIG. 5 illustrates a cross-sectional view showing a semiconductor device according to some embodiments;

FIG. 6 illustrates a cross-sectional view showing a semiconductor device according to some embodiments;

FIG. 7 illustrates a cross-sectional view showing a semiconductor device according to some embodiments; and

FIG. 8 illustrates a cross-sectional view showing a semiconductor device according to some embodiments.

### DETAILED DESCRIPTION OF EMBODIMENTS

The following will describe a semiconductor device and a method of fabricating the same according to some embodiments of the present inventive concepts in conjunction with the accompanying drawings.

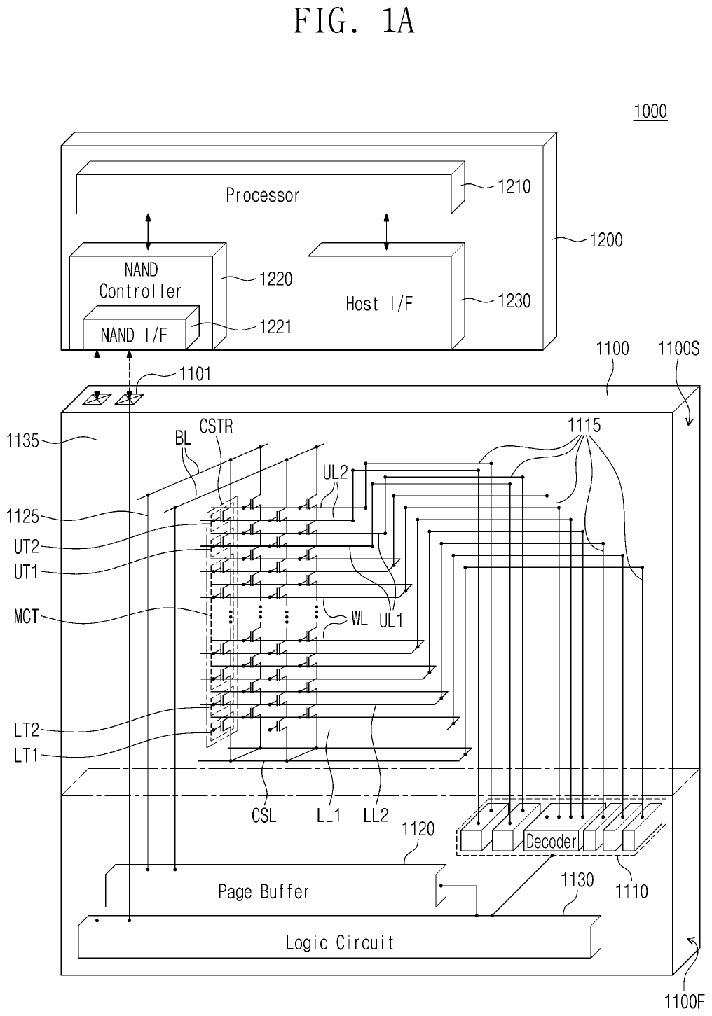

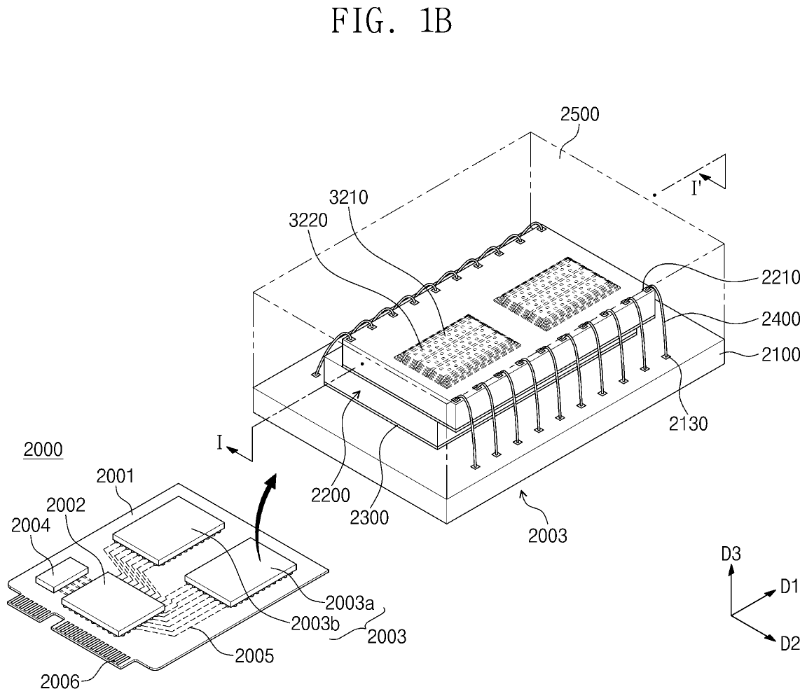

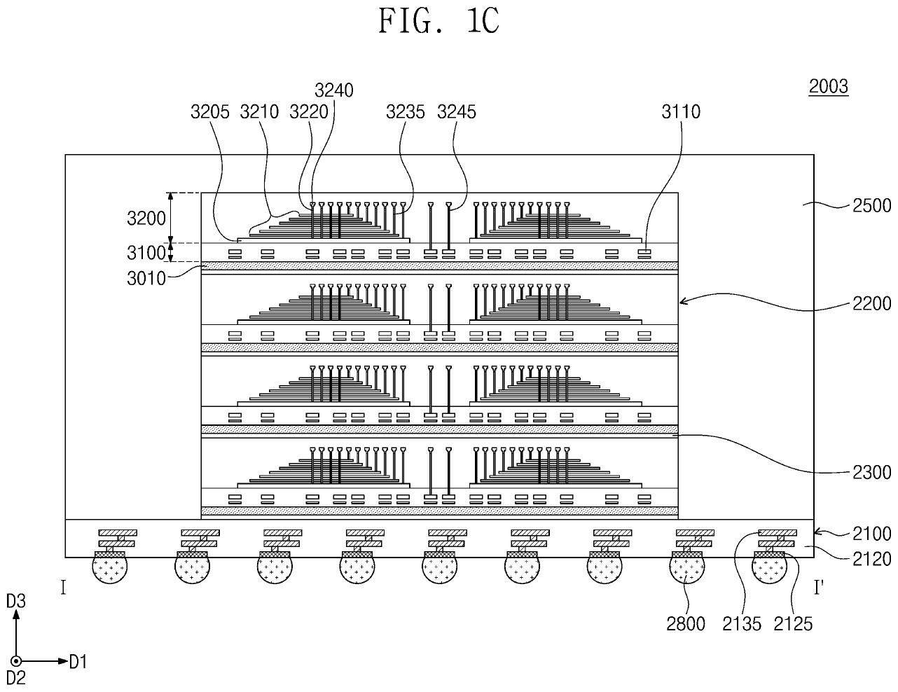

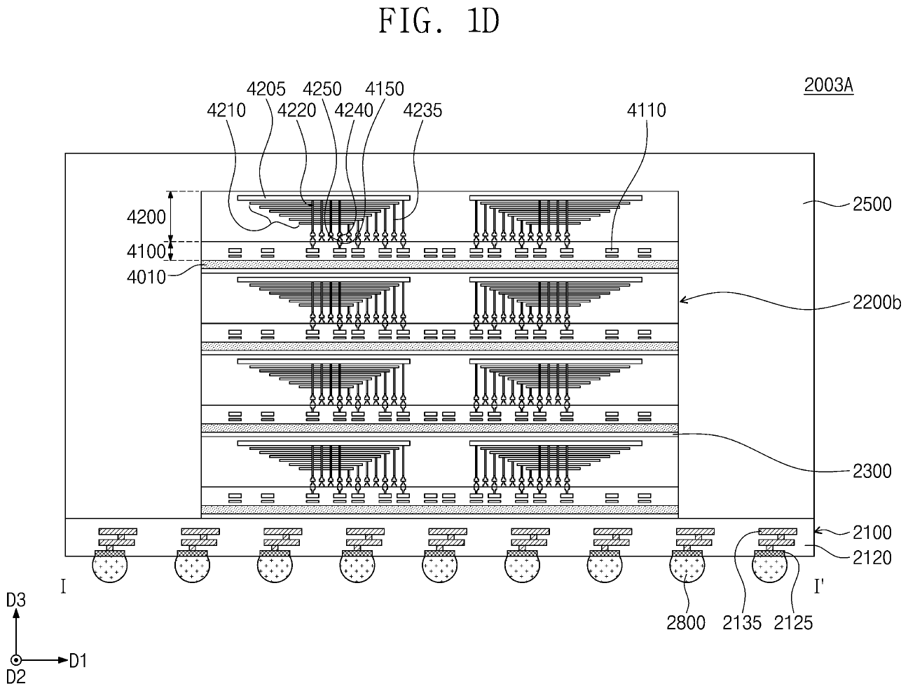

FIG. 1A illustrates a simplified block diagram showing an electronic system including a semiconductor device according to some embodiments.

Referring to FIG. 1A, an electronic system 1000 according to some embodiments may include a semiconductor device 1100 and a controller 1200 electrically connected to the semiconductor device 1100. By way of illustration only and without limitation, the electronic system 1000 may be a storage device that includes a single or a plurality of semiconductor devices 1100, or may be an electronic device that includes the storage device. For example, the electronic system 1000 may be a solid-state drive (SSD) device, a universal serial bus (USB) device or system, a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on one side of the second structure 1100S. The first structure 1100F may be a peripheral circuit structure that includes a decoder circuit 1110, a page buffer 1120, and a logic circuit 1130. The second structure 1100S may be a memory cell structure that includes one or more bit lines BL, a common source line CSL, word lines WL, first and second gate upper lines UL1 and UL2, first and second gate lower lines LL1 and LL2, and memory cell strings CSTR between the bit lines BL and the common source line CSL.

On the second structure 1100S, each of the memory cell strings CSTR may include lower transistors LT1 and LT2 adjacent to the common source line CSL, upper transistors UT1 and UT2 adjacent to a corresponding bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F to the second structure 1100S. The bit lines BL may be electrically connected to the page buffer 1120 through second connection lines 1125 that extend from the first structure 1100F to the second structure 1100S.

On the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through at least one input/output pad 1101 electrically connected to the logic circuit 1130. The input/output pad 1101 may be electrically connected to the logic circuit 1130 through at least one input/output connection line 1135 that extends from the first structure 1100F to the second structure 1100S.

The controller 1200 may include a processor 1210, a controller (e.g., NAND controller) 1220, and a host interface (I/F) 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that is configured to process communication with the semiconductor device 1100. For example, the NAND interface 1221 may be used to transfer therethrough a control command to control the semiconductor device 1100, data intended to be written to the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

FIG. 1B illustrates a simplified perspective view showing an electronic system including a semiconductor device according to some embodiments.

Referring to FIG. 1B, an electronic system 2000 according to some example embodiments may include a main board 2001, a controller 2002 mounted on the main board 2001, at least one semiconductor package 2003, and a dynamic random-access memory (DRAM) 2004. The semiconductor package 2003 and the DRAM 2004 may be connected to the controller 2002 through wiring patterns 2005 formed on the main board 2001.

The main board 2001 may include a connector 2006 including a plurality of pins which will be connected to an external host. The number and arrangement of the plurality of pins on the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PCI-Express or PCIe), serial advanced technology attachment (SATA), and/or M-PHY for universal flash storage (UFS). In some embodiments, the electronic system 2000 may operate with power supplied through the connector 2006 from an external host. The electronic system 2000 may further include a power management integrated circuit (PMIC) by which the power supplied from the external host is distributed to the controller 2002 and the semiconductor package(s) 2003.

The controller 2002 may write data to the semiconductor package 2003, may read data from the semiconductor package 2003, or may increase an operating speed of the electronic system 2000.

The DRAM 2004 may comprise a buffer memory configured to accommodate for a difference in speed between an external host and the semiconductor package 2003 (e.g., for data synchronization) that serves as a data storage space, in some embodiments. The DRAM 2004 included in the electronic system 2000 may be configured to operate as a kind of cache memory, and may provide a space for temporary data storage in a control operation of the semiconductor package 2003, in some embodiments. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 on bottom surfaces of the semiconductor chips 2200, connection structures 2400 that electrically connect the semiconductor chips 2200 to the package substrate 2100, and a molding layer 2500 that lies on the package substrate 2100 and covers (e.g., encapsulates) the semiconductor chips 2200 and the connection structures 2400.

The package substrate 2100 may be an integrated circuit board including package upper pads 2130 formed on a surface of the substrate 2100. Each of the semiconductor chips 2200 may include one or more input/output pads 2210. The input/output pad 2210 may correspond to the input/output pad 1101 of FIG. 1A. Each of the semiconductor chips 2200 may include gate stack structures 3210 and memory channel structures 3220. Each of the semiconductor chips 2200 may include a semiconductor device embodiments of which will be discussed below.

In some embodiments, the connection structures 2400 may be bonding wires that electrically connect the input/output pads 2210 to the package upper pads 2130. Therefore, on each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, on each of the first and second semiconductor packages 2003a and 2003b, the semiconductor chips 2200 may be electrically connected to each other using through-silicon vias (TSVs) instead of the connection structures 2400 or the bonding wires.

In some embodiments, the controller 2002 and the semiconductor chips 2200 may be included in one package. In some embodiments, the controller 2002 and the semiconductor chips 2200 may be mounted on a separate interposer substrate (not explicitly shown, but implied) other than the main board 2001, and may be connected to each other through wiring lines provided in the interposer substrate.

FIGS. 1C and 1D illustrate simplified cross-sectional views showing a semiconductor package according to some embodiments. FIGS. 1C and 1D each depicts an exemplary embodiment of the semiconductor package 2003 shown in FIG. 1B, conceptually showing a section taken along line I-I′ of the semiconductor package 2003 shown in FIG. 1B.

Referring to FIG. 1C, a printed circuit board may be used as the package substrate 2100 of the semiconductor package 2003. The package substrate 2100 may include a package substrate body 2120, upper pads (see 2130 of FIG. 1B) disposed on a top surface of the package substrate body 2120, lower pads 2125 disposed or exposed on a bottom surface of the package substrate body 2120, and internal lines 2135 that lie in the package substrate body 2120 and electrically connect the upper pads 2130 to the lower pads 2125. The upper pads 2130 may be electrically connected to connection structures (see 2400 of FIG. 1B). The lower pads 2125 may be connected through conductive connection parts 2800 (e.g., solder balls, C4 bumps, etc.) to the wiring patterns 2005 on the main board 2001 of the electronic system 2000, as shown in FIG. 1B.

Each of at least a subset of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, memory channel structures 3220 that penetrate through the gate stack structure 3210, bit lines 3240 electrically connected to the memory channel structures 3220, and gate contact plugs 3235 electrically connected to corresponding word lines (see WL of FIG. 1A) of the gate stack structure 3210.

Each of at least a subset of the semiconductor chips 2200 may include through wiring lines 3245 that are electrically connected to the peripheral wiring lines 3110 of the first structure 3100 and extend into the second structure 3200. The through wiring line 3245 may be disposed outside the gate stack structure 3210. In some embodiments, the through wiring line 3245 may penetrate through the gate stack structure 3210. Each of the semiconductor chips 2200 may further include an input/output pad (see 2210 of FIG. 1B).

Referring to FIG. 1D, on a semiconductor package 2003A, each of semiconductor chips 2200b may include a semiconductor substrate 4010, a first structure 4100 on the semiconductor substrate 4010, and a second structure 4200 provided on and wafer-bonded to the first structure 4100.

The first structure 4100 may include a peripheral circuit region including a peripheral wiring line 4110 and first bonding structures 4150. The second structure 4200 may include a common source line 4205, a gate stack structure 4210 between the common source line 4205 and the first structure 4100, memory channel structures 4220 that penetrate through the gate stack structure 4210, bit lines 4240 electrically connected to the memory channel structures 4220, gate contact plugs 4235 electrically connected to corresponding word lines (see WL of FIG. 1A) of the gate stack structure 4210, and second bonding structures 4250. For example, the second bonding structures 4250 may be electrically connected to corresponding memory channel structures 4220 through the bit lines 4240 electrically connected to the memory channel structures 4220. The first bonding structures 4150 of the first structure 4100 may be bonded to the second bonding structures 4250 of the second structure 4200. The first and second bonding structures 4150 and 4250 may have their bonding portions formed of, for example, copper (Cu). Each of the semiconductor chips 2200b may further include an input/output pad (see 2210 of FIG. 1B).

The semiconductor chips 2200 of FIG. 1C or the semiconductor chips 2200b of FIG. 1D may be electrically connected to each other through the connection structures (see 2400 of FIG. 1B) shaped like bonding wires. In some embodiments, semiconductor chips in one semiconductor package, such as the semiconductor chips 2200 of FIG. 1C or the semiconductor chips 2200b of FIG. 1D, may be electrically connected to each other through connection structures including through electrodes (TSVs).

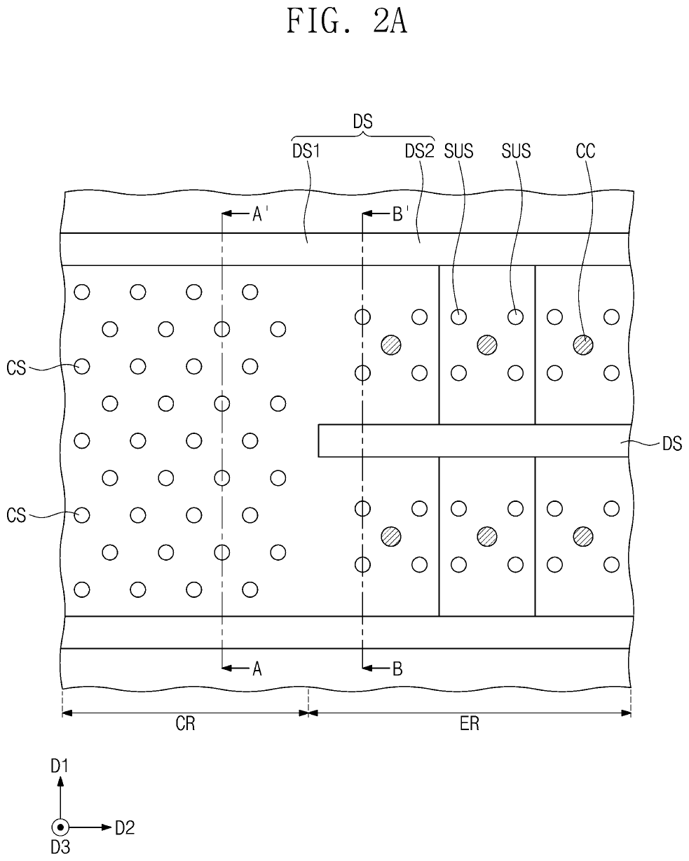

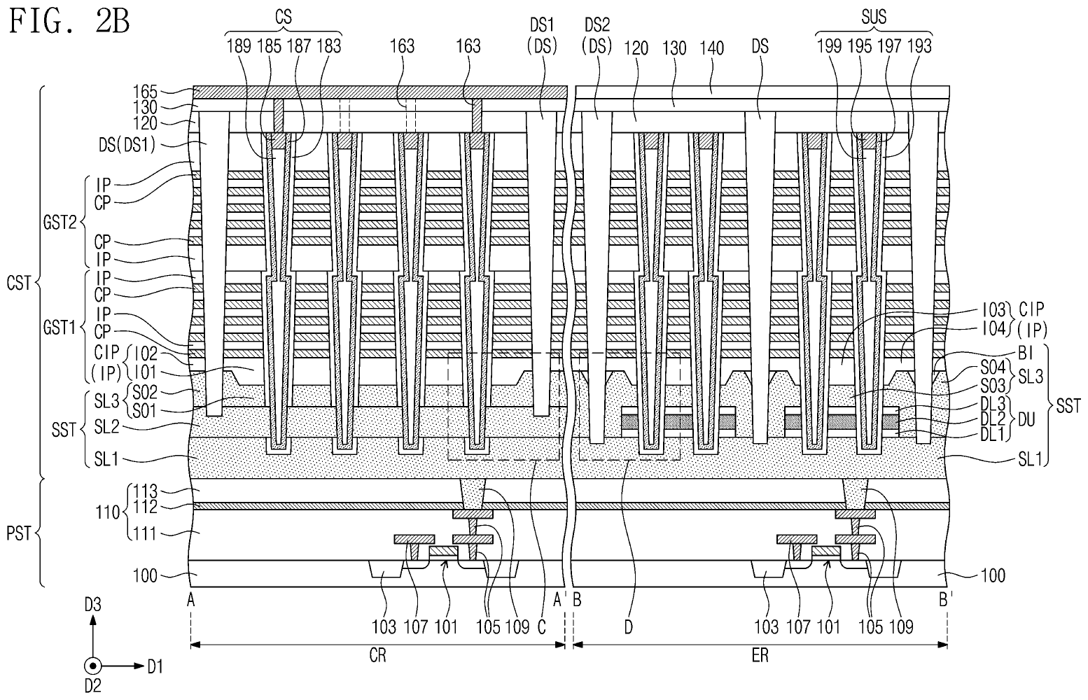

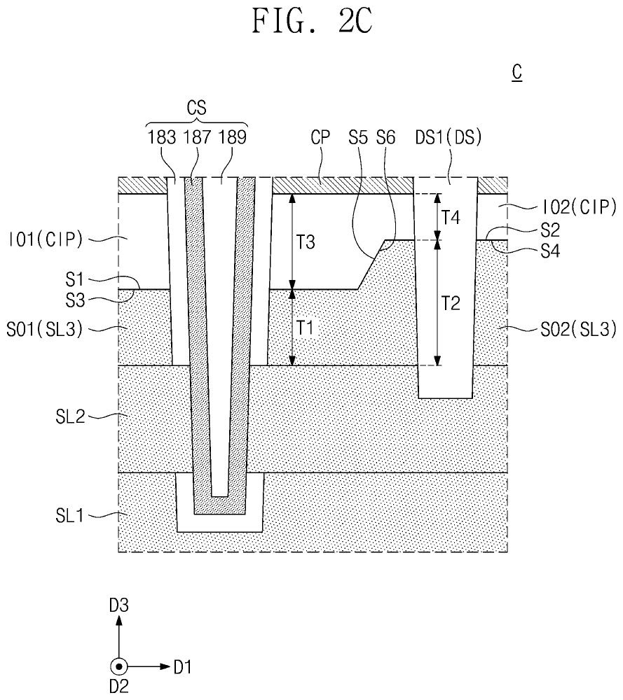

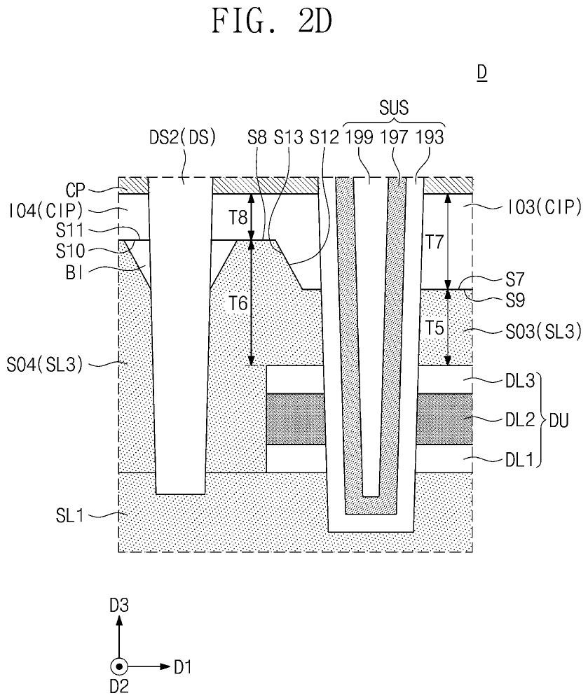

FIG. 2A illustrates a plan view showing a semiconductor device according to some embodiments. FIG. 2B illustrates a cross-sectional view taken along lines A-A′ and B-B′ of FIG. 2A. FIG. 2C illustrates an enlarged view showing section C of FIG. 2B. FIG. 2D illustrates an enlarged view showing section D of FIG. 2B.

Referring to FIGS. 2A, 2B, 2C, and 2D, a semiconductor device may include a peripheral circuit structure PST and a memory cell structure CST on the peripheral circuit structure PST.

The peripheral circuit structure PST may include a substrate 100. The substrate 100 may have a plate shape that expands along a plane defined by a first direction D1 and a second direction D2. The first direction D1 and the second direction D2 may intersect each other. For example, the first direction D1 and the second direction D2 may be horizontal directions that are orthogonal to each other. In some embodiments, the substrate 100 may be a semiconductor substrate. For example, the substrate 100 may include silicon (Si), germanium (Ge), silicon-germanium (SiGe), gallium phosphide (GaP), or gallium arsenide (GaAs). In some embodiments, the substrate 100 may be a silicon-on-insulator (SOI) substrate or a germanium-on-insulator (GOI) substrate.

The peripheral circuit structure PST may include a peripheral circuit dielectric structure 110 on the substrate 100. The peripheral circuit dielectric structure 110 may include a first peripheral circuit dielectric layer 111, a second peripheral circuit dielectric layer 112 on the first peripheral circuit dielectric layer 111, and a third peripheral circuit dielectric layer 113 on the second peripheral circuit dielectric layer 112. Each of the first, second, and third peripheral circuit dielectric layers 111, 112, and 113 may include a dielectric material. For example, the first and third peripheral circuit dielectric layers 111 and 113 may include oxide, and the second peripheral circuit dielectric layer 112 may include nitride. In some embodiments, each of the first, second, and third peripheral circuit dielectric layers 111, 112, and 113 may be a multiple dielectric layer.

The peripheral circuit structure PST may further include a peripheral transistor 101. The peripheral transistor 101 may be provided between the substrate 100 and the peripheral circuit dielectric structure 110. In some embodiments, the peripheral transistor 101 may include source/drain regions, a gate electrode, and a gate dielectric layer. The substrate 100 may have device isolation layers 103 therein. The peripheral transistor 101 may be disposed between the device isolation layers 103. The device isolation layer 103 may include a dielectric material.

The peripheral circuit structure PST may further include peripheral contacts 105 and peripheral conductive lines 107. The peripheral contact 105 may be connected to the peripheral transistor 101 or the peripheral conductive line 107, and the peripheral conductive line 107 may be connected to the peripheral contact 105. The peripheral contact 105 and the peripheral conductive line 107 may be provided in the first peripheral circuit dielectric layer 111 of the peripheral circuit dielectric structure 110. The peripheral contact 105 and the peripheral conductive line 107 may include a conductive material. For example, the peripheral contact 105 and the peripheral conductive line 107 may include metal.

The peripheral circuit structure PST may further include a source connection contact 109. The source connection contact 109 may be connected to the peripheral conductive line 107 and a base source layer SL1 which will be discussed below. The source connection contact 109 may penetrate through the second and third peripheral circuit dielectric layers 112 and 113, respectively, of the peripheral circuit dielectric structure 110. The source connection contact 109 may include a conductive material. For example, the source connection contact 109 may include polysilicon.

The memory cell structure CST may include a source structure SST, a first gate stack structure GST1, a second gate stack structure GST2, memory channel structures CS, support structures SUS, a first cover dielectric layer 120, a second cover dielectric layer 130, a third cover dielectric layer 140, separation structures DS, bit-line contacts 163, bit lines 165, and connection contacts CC.

The source structure SST may include a cell region CR and an extension region ER. The cell region CR and the extension region ER may be areas divided in the first direction D1 and the second direction D2 when viewed in plan.

The source structure SST may include a base source layer SL1 on the peripheral circuit structure PST, an intervening source layer SL2 on the base source layer SL1, dummy source structures DU on the base source layer SL1, and a support source layer SL3 on the intervening source layer SL2 and the dummy source structures DU. The intervening source layer SL2 may be provided in the cell region CR of the source structure SST. The dummy source structure DU may be provided in the extension region ER of the source structure SST. The intervening source layer SL2 may be interposed between the base source layer SL1 and the support source layer SL3. The dummy source structure DU may be interposed between the base source layer SL1 and the support source layer SL3. The support source layer SL3 may cover the intervening source layer SL2 and the dummy source structures DU.

The base source layer SL1, the intervening source layer SL2, and the support source layer SL3 may include a conductive material. For example, the base source layer SL1, the intervening source layer SL2, and the support source layer SL3 may include polysilicon. The intervening source layer SL2 may be a common source line.

The dummy source structure DU may include a first dummy layer DL1, a second dummy layer DL2, and a third dummy layer DL3. The first, second, and third dummy layers DL1, DL2, and DL3 may be sequentially provided along a third direction D3. The third direction D3 may intersect the first direction D1 and the second direction D2. For example, the third direction D3 may be a vertical direction perpendicular to the first direction D1 and the second direction D2. The first, second, and third dummy layers DL1, DL2, and DL3 may include a dielectric material. In some embodiments, the first and third dummy layers DL1 and DL3 may include the same dielectric material, and the second dummy layer DL2 may include a dielectric material different from that of the first and third dummy layers DL1 and DL3. For example, the second dummy layer DL2 may include nitride, and the first and third dummy layers DL1 and DL3 may include oxide.

The source structure SST may further include a buried dielectric layer BI on the support source layer SL3. The buried dielectric layer BI may be provided in the extension region ER of the source structure SST. The buried dielectric layer BI may include a dielectric material.

The first gate stack structure GST1 may be provided on the support layer SL3 of the source structure SST. The second gate stack structure GST2 may be provided on the first gate stack structure GST1. The number of the gate stack structures GST1 and GST2 may not be limited to that shown. In some embodiments, the number of the gate stack structures GST1 and GST2 may be one or three or more.

Each of the first and third gate stack structures GST1 and GST2 may include dielectric patterns IP and conductive patterns CP that are alternately stacked along the third direction D3. The dielectric patterns IP may include a dielectric material. For example, the dielectric patterns IP may include oxide. The conductive patterns CP may include a conductive material. For example, the conductive patterns CP may include tungsten.

The dielectric patterns IP of the first gate stack structure GST1 may include a connection dielectric pattern CIP in contact with the support source layer SL3. The connection dielectric pattern CIP may be disposed at bottom of the dielectric patterns IP.

The memory channel structures CS may extend in the third direction D3 to penetrate through the first gate stack structure GST1, the second gate stack structure GST2, the support source layer SL3, and the intervening source layer SL2. Each of the memory channel structures CS may include a dielectric capping layer 189, a channel layer 187 that surrounds the dielectric capping layer 189, and a memory layer 183 that surrounds the channel layer 187.

The dielectric capping layer 189 may include a dielectric material. For example, the dielectric capping layer 189 may include oxide. The channel layer 187 may include a conductive material. For example, the channel layer 187 may include polysilicon. The channel layer 187 may be electrically connected to the intervening source layer SL2 of the source structure SST. The intervening source layer SL2 may penetrate through the memory layer 183 to come into connection with the channel layer 187. The intervening source layer SL2 may extend around (e.g., surround) the memory channel structure CS.

The memory layer 183 may store data. In some embodiments, the memory layer 183 may include a tunnel dielectric layer that surrounds the channel layer 187, a data storage layer that surrounds the tunnel dielectric layer, and a blocking layer that surrounds the data storage layer.

Each of the memory channel structures CS may further include a bit-line pad 185 provided on the channel layer 187. The bit-line pad 185 may include a conductive material. For example, the bit-line pad 185 may include polysilicon or metal.

The support structures SUS may extend in the third direction D3 to penetrate through the first gate stack structure GST1, the second gate stack structure GST2, the support source layer SL3, and the dummy source structure DU. The support structure SUS may include a first support layer 199, a second support layer 197 that surrounds the first support layer 199, and a third support layer 193 that surrounds the second support layer 197. The support structure SUS may further include a support pad 195 on the first support layer 199. The support structure SUS may have a structure similar to that of the memory channel structure CS. The first support layer 199 may have a structure similar to that of the dielectric capping layer 189, the second support layer 197 may have a structure similar to that of the channel layer 187, the third support layer 193 may have a structure similar to that of the memory layer 183, and the support pad 195 may have a structure similar to that of the bit-line pad 185. The support structure SUS may be electrically separated from the source structure SST. The dummy source structure DU may surround the support structure SUS.

The connection contact CC may be disposed between the support structures SUS. The connection contact CC may be connected to the conductive pattern CP. The connection contact CC may include a conductive material.

The first cover dielectric layer 120 may be provided on the second gate stack structure GST2, the memory channel structures CS, and the support structures SUS. The first cover dielectric layer 120 may include a dielectric material.

The separation structures DS may extend in the third direction D3 to penetrate through the first cover dielectric layer 120, the first gate stack structure GST1, and the second gate stack structure GST2. The separation structures DS may extend in the second direction D2. The memory channel structures CS, the support structures SUS, and the connection contacts CC may be disposed between the separation structures DS.

At least one of the separation structures DS may include a first separation part DS1 adjacent to the memory channel structure CS and a second separation part DS2 adjacent to the support structure SUS. A distance between the first separation part DS1 and the support structure SUS may be greater than a distance between the first separation part DS1 and the memory channel structure CS. A distance between the second separation part DS2 and the memory channel structure CS may be greater than a distance between the second separation part DS2 and the support structure SUS. In some embodiments, the separation structure DS may have a single unitary structure formed of a dielectric material. In some embodiments, the separation structure DS may include a dielectric layer and a conductive layer in the dielectric layer.

The second cover dielectric layer 130 may be provided on the first cover dielectric layer 120. The second cover dielectric layer 130 may include a dielectric material. The third cover dielectric layer 140 may be provided on the second cover dielectric layer 130. The third cover dielectric layer 140 may include a dielectric material.

The bit-line contact 163 may penetrate through the first and second cover dielectric layers 120 and 130, respectively, to come into connection with the bit-line pad 185. The bit line 165 may be connected to the bit-line contact 163. The bit line 165 may be disposed in the third cover dielectric layer 140. The bit line 165 may extend in the first direction D1. The bit line 165 may be electrically connected through the bit-line contact 163 to the memory channel structure CS. The bit-line contact 163 and the bit line 165 may include a conductive material. The bit-line contact 163 and the bit line 165 may be formed of the same conductive material or may comprise different conductive materials.

The support source layer SL3 may include a first source part SO1 through which the memory channel structure CS penetrates, a second source part SO2 through which the first separation part DS1 of the separation structure DS penetrates, a third source part SO3 through which the support structure SUS penetrates, and a fourth source part SO4 through which the second separation part DS2 of the separation structure DS penetrates. The first source part SO1 may be in contact with the memory channel structure CS, the second source part SO2 may be in contact with the first separation part DS1 of the separation structure DS, the third source part SO3 may be in contact with the support structure SUS, and the fourth source part SO4 may be in contact with the second separation part DS2 of the separation structure DS.

The connection dielectric pattern CIP may include a first dielectric part IO1 through which the memory channel structure CS penetrates, a second dielectric part IO2 through which the first separation part DS1 of the separation structure DS penetrates, a third dielectric part IO3 through which the support structure SUS penetrates, and a fourth dielectric part IO4 through which the second separation part DS2 of the separation structure DS penetrates. The first dielectric part IO1 may be in contact with the memory channel structure CS, the second dielectric part IO2 may be in contact with the first separation part DS1 of the separation structure DS, the third dielectric part IO3 may be in contact with the support structure SUS, and the fourth dielectric part IO4 may be in contact with the buried dielectric layer BI and the second separation part DS2 of the separation structure DS.

The first source part SO1 may include a first contact surface S1 in contact with the first dielectric part IO1. The second source part SO2 may include a second contact surface S2 in contact with the second dielectric part IO2. The third source part SO3 may include a third contact surface S7 in contact with the third dielectric part IO3. The fourth source part SO4 may include a fourth contact surface S8 in contact with the fourth dielectric part IO4. The first contact surface 51 may be a top surface of the first source part SO1. The second contact surface S2 may be a top surface of the second source part SO2. The third contact surface S7 may be a top surface of the third source part SO3. The fourth contact surface S8 may be a top surface of the fourth source part SO4.

The first dielectric part IO1 may include a fifth contact surface S3 in contact with the first contact surface S1 of the first source part SO1. The second dielectric part IO2 may include a sixth contact surface S4 in contact with the second contact surface S2 of the second source part SO2. The third dielectric part IO3 may include a seventh contact surface S9 in contact with the third contact surface S7 of the third source part SO3. The fourth dielectric part IO4 may include an eighth contact surface S10 in contact with the fourth contact surface S8 of the fourth source part SO4. The fifth contact surface S3 may be a bottom surface of the first dielectric part IO1. The sixth contact surface S4 may be a bottom surface of the second dielectric part IO2. The seventh contact surface S9 may be a bottom surface of the third dielectric part IO3. The eighth contact surface 510 may be a bottom surface of the fourth dielectric part IO4.

The buried dielectric layer BI may include a ninth contact surface S11 in contact with the eighth contact surface S10 of the fourth dielectric part IO4. The ninth contact surface S11 may be a top surface of the buried dielectric layer BI.

The first contact surface S1, the third contact surface S7, the fifth contact surface S3, and the seventh contact surface S9 may be located at their levels different from those of the second contact surface S2, the fourth contact surface S8, the sixth contact surface S4, the eighth contact surface S10, and the ninth contact surface S11. The first contact surface S1, the third contact surface S7, the fifth contact surface S3, and the seventh contact surface S9 may be located at their levels lower than those of the second contact surface S2, the fourth contact surface S8, the sixth contact surface S4, the eighth contact surface S10, and the ninth contact surface S11. In some embodiments, the first contact surface S1, the third contact surface S7, the fifth contact surface S3, and the seventh contact surface S9 may be located at the same level. In some embodiments, the second contact surface S2, the fourth contact surface S8, the sixth contact surface S4, the eighth contact surface S10, and the ninth contact surface S11 may be located at the same level.

The support source layer SL3 may include a first connection surface S5 that connects the first contact surface S1 to the second contact surface S2, and may also include a second connection surface S12 that connects the third contact surface S7 to the fourth contact surface S8. The first connection surface S5 and the second connection surface S12 may be inclined. The first connection surface S5 may have a level that rises in a direction from the first contact surface S1 to the second contact surface S2. The second connection surface S12 may have a level that rises in a direction from the third contact surface S7 to the fourth contact surface S8.

The connection dielectric pattern CIP may include a third connection surface S6 in contact with the first connection surface S5 and a fourth connection surface S13 in contact with the second connection surface S12. The third connection surface S6 may connect the fifth contact surface S3 to the sixth contact surface S4. The fourth connection surface S13 may connect the seventh contact surface S9 to the eighth contact surface S10. The third connection surface S6 and the fourth connection surface S13 may be inclined.

A thickness T1 in the third direction D3 of the first source part SO1 and a thickness T5 in the third direction D3 of the third source part SO3 may be less than a thickness T2 in the third direction D3 of the second source part SO2, a thickness T6 in the third direction D3 between the fourth contact surface S8 and a top surface of the dummy source structure DU, a thickness T3 in the third direction D3 of the first dielectric part IO1, and a thickness T7 in the third direction D3 of the third dielectric layer 103.

The thickness T1 in the third direction D3 of the first source part SO1 and the thickness T5 in the third direction D3 of the third source part SO3 may be greater than a thickness T4 in the third direction D3 of the second dielectric part IO2 and a thickness T8 in the third direction D3 of the fourth dielectric part IO4.

In a semiconductor device according to some embodiments, because a relatively small thickness is given to the first source part SO1 through which the memory channel structure CS penetrates and to the third source part SO3 through which the support structure SUS penetrates, and because a relatively large thickness is given to the second source part SO2 through which the separation structure DS penetrates, it may be possible to improve a process margin for forming the memory channel structure CS, the support structure SUS, and the separation structure DS.

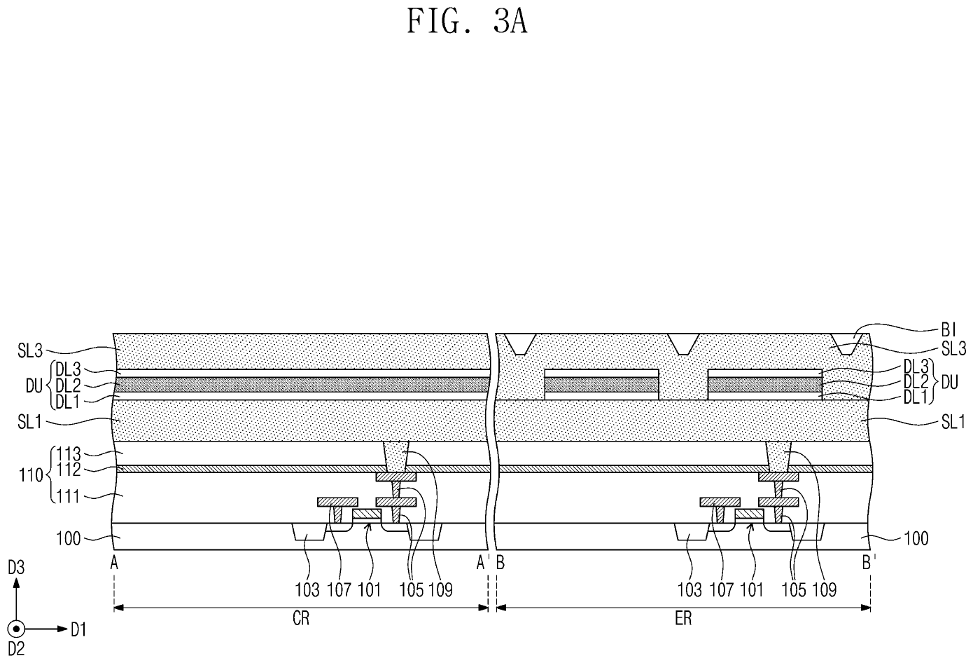

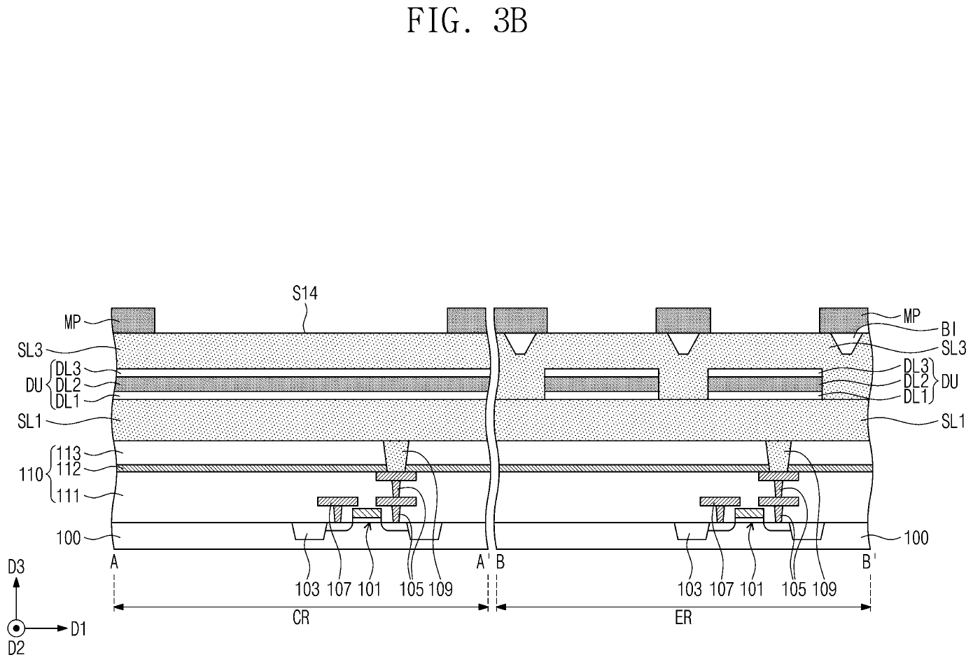

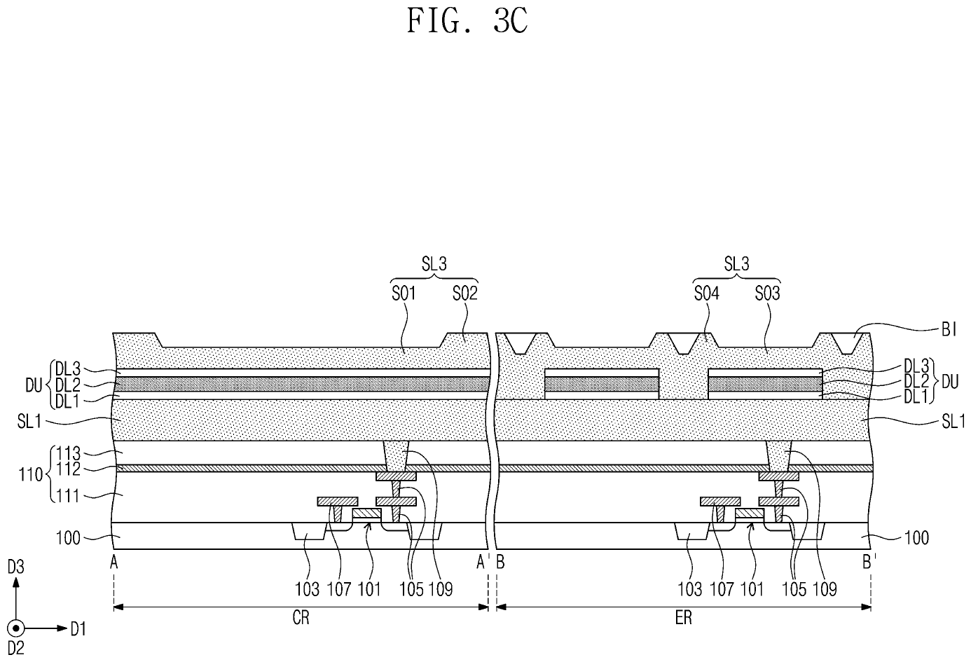

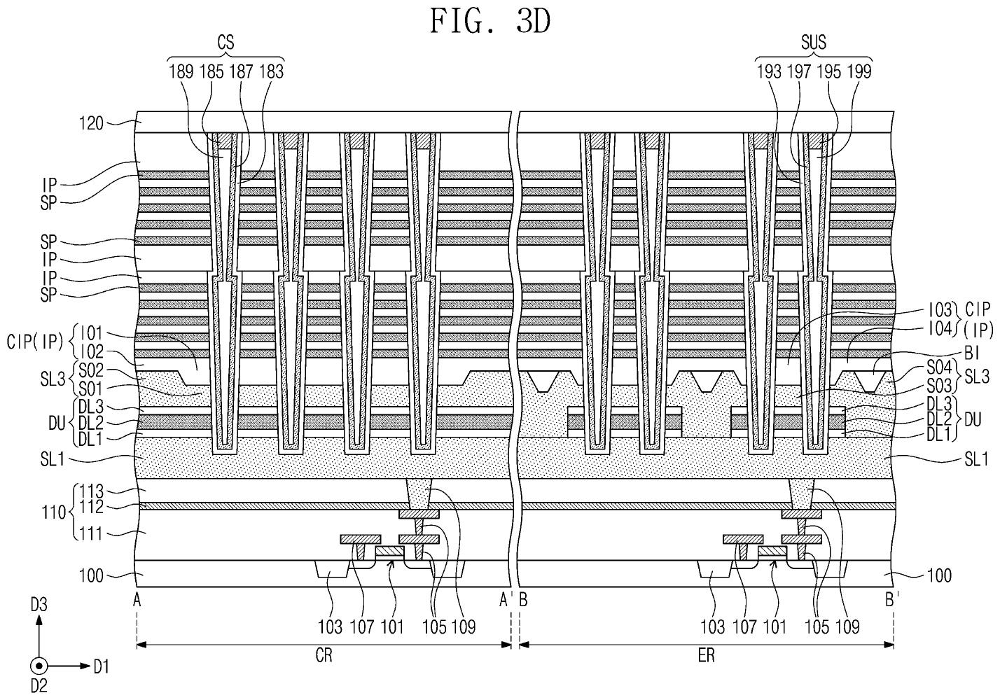

FIGS. 3A, 3B, 3C, and 3D illustrate cross-sectional views showing a method of fabricating the semiconductor device depicted in FIGS. 2A, 2B, 2C, and 2D. FIGS. 3A, 3B, 3C, and 3D may correspond to FIG. 2B.

Referring to FIG. 3A, a substrate 100 may be provided with a device isolation layer 103, peripheral transistors 101, peripheral contacts 105, peripheral conductive lines 107, a source connection contact 109, and a peripheral circuit dielectric structure 110 that are formed thereon. The peripheral circuit dielectric structure 110 may include a first peripheral circuit dielectric layer 111, a second peripheral circuit dielectric layer 112, and a third peripheral circuit dielectric layer 113.

A base source layer SL1 may be formed on the peripheral circuit dielectric structure 110. A dummy source structure DU may be formed on the base source layer SL1. The dummy source structure DU may be formed on a cell region CR and an extension region ER. The dummy source structure DU may include a first dummy layer DL1, a second dummy layer DL2, and a third dummy layer DL3 formed as a stacked structure in the direction D3.

A support source layer SL3 may be formed on the dummy source structure DU. The formation of the support source layer SL3 may include etching the dummy source structure DU of the extension region ER and forming the support source layer SL3 to fill a space formed by etching the dummy source structure DU. Buried dielectric layers BI may be formed on the support source layer SL3 of the extension region ER.

Referring to FIG. 3B, a mask pattern MP may be formed on the support source layer SL3 and the buried dielectric layers BI. In some embodiments, the mask pattern MP may be a photoresist pattern. The mask pattern MP may partially expose a top surface S14 of the support source layer SL3. The mask pattern MP may cover a top surface of the buried dielectric layers BI.

Referring to FIG. 3C, the mask pattern MP may be used as an etching mask to perform an etching process to at least partially etch the support source layer SL3. The etching process may etch a portion of the top surface S14 of the support source layer SL3 exposed by the mask pattern MP. The support source layer SL3 may undergo an etching process to define first, second, third, and fourth source parts SO1, SO2, SO3, and SO4, respectively. The etching process may be performed to allow the first and third source parts SO1 and SO3 to have their thicknesses in a third direction D3 (i.e., cross-sectional thickness) reduced so that they are less than thicknesses in the third direction D3 of the second and fourth source parts SO2 and SO4.

Referring to FIG. 3D, dielectric layers and sacrificial layers may be formed on the etched support source layer SL3. The sacrificial layer and the dielectric layer may include different dielectric materials from each other. For example, the sacrificial layer may include nitride, and the dielectric layer may include oxide. Memory channel structures CS and the support structures SUS may be formed to penetrate through the support source layer SL3, the dielectric layers, and the sacrificial layers. The memory channel structure CS may include a dielectric capping layer 189, a channel layer 187, a bit-line pad 185, and a memory layer 183. The support structure SUS may include a first support layer 199, a second support layer 197, a third support layer 193, and a support pad 195.

Dielectric patterns IP may be defined to indicate the dielectric layers through which the memory channel structures CS and the support structures SUS penetrate. A connection dielectric pattern CIP may be defined to indicate a lowermost one of the dielectric patterns IP. The connection dielectric pattern CIP may include first, second, third, and fourth dielectric parts 101, 102, 103, and 104. The first, second, third, and fourth dielectric parts 101, 102, 103, and 104 of the connection dielectric pattern CIP may correspond to the first, second, third, and fourth source parts SO1, SO2, SO3, and SO4 of the support source layer SL3, and thicknesses in the third direction D3 of the first and third dielectric parts 101 and 103 in the connection dielectric pattern CIP may be greater than thicknesses in the third direction D3 of the second and fourth dielectric parts 102 and 104 of the connection dielectric pattern CIP.

Sacrificial patterns SP may be defined to indicate the sacrificial layers through which the memory channel structures CS and the support structures SUS penetrate. A first cover dielectric layer 120 may be formed to cover the dielectric pattern IP, the memory channel structures CS, and the support structures SUS.

Referring to FIG. 2B, there may be formed separation structures DS, conductive patterns CP, and an intervening source layer SL2. The formation of the separation structures DS, the conducive patterns CP, and the intervening source layer SL2 may include forming trenches that penetrate through the dielectric patterns IP and the sacrificial patterns SP, using the trenches to remove the dummy source structure DU of the cell region CR, forming the intervening source layer SL2 in an empty space formed when the dummy source structure DU of the cell region CR is removed, using the trenches to remove the sacrificial patterns SP, forming the conductive patterns CP in empty spaces formed when the sacrificial patterns SP are removed, and forming the separation structures DS in the trenches. In some embodiments, the formation of the conductive patterns CP may be followed by the formation of the intervening source layer SL2. In some embodiments, the formation of the intervening source layer SL2 may be followed by the formation of the conductive patterns CP.

A second cover dielectric layer 130 may be formed on the separation structures DS and the first cover dielectric layer 120. Bit-line contact 163 may be formed to penetrate through the first and second cover dielectric layers 120 and 130.

A third cover dielectric layer 140 may be formed on the second cover dielectric layer 130. Bit lines 165 may be formed in the third cover dielectric layer 140.

In a method of fabricating a semiconductor device according to some embodiments, as a relatively small thickness is given to the first and third source parts SO1 and SO3 of the support source layer SL3, the memory channel structure CS and the support structure SUS may be prevented from not penetrating the source dummy source structure DU in a process for forming the memory channel structure CS and the support structure SUS.

In a method of fabricating a semiconductor device according to some embodiments, as a relatively large thickness is given to the second source part SO2 of the support source layer SL3, the trench for forming the separation structure DS may be prevented from completely penetrating the dummy source structure DU of the cell region CR.

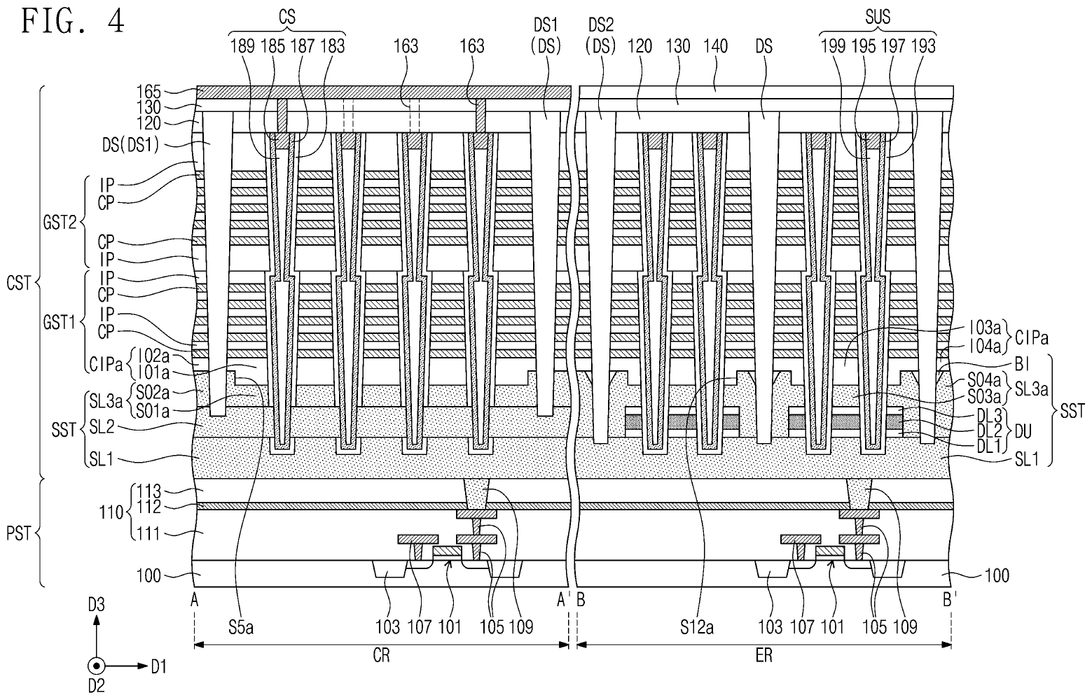

FIG. 4 illustrates a cross-sectional view showing a semiconductor device according to some embodiments.

Referring to FIG. 4, a support source layer SL3a of a semiconductor device may include a first source part SO1a through which the memory channel structure CS penetrates, a second source part SO2a through which the first separation part DS1 of the separation structure DS penetrates, a third source part SO3a through which the support structure SUS penetrates, and a fourth source part SO4a through which the second separation part DS2 of the separation structure DS penetrates.

A connection dielectric pattern CIPa in contact with the support source layer SL3a may include a first dielectric part IO1a in contact with the first source part SO1a, a second dielectric part IO2a in contact with the second source part SO2a, a third dielectric part IO3a in contact with the third source part SO3a, and a fourth dielectric part IO4a in contact with the fourth source part SO4a.

The support source layer SL3a may include a first connection surface S5a that connects a top surface of the first source part SO1a to a top surface of the second source part SO2a. The first connection surface S5a of the support source layer SL3a may be a sidewall that is orthogonal to the top surface of the first source part SO1a and the top surface of the second source part SO2a. The support source layer SL3a may include a second connection surface 512a that connects a top surface of the third source part SO3a to a top surface of the fourth source part SO4a. The second connection surface 512a of the support source layer SL3a may be a sidewall that is orthogonal to the top surface of the third source part SO3a and the top surface of the fourth source part SO4a.

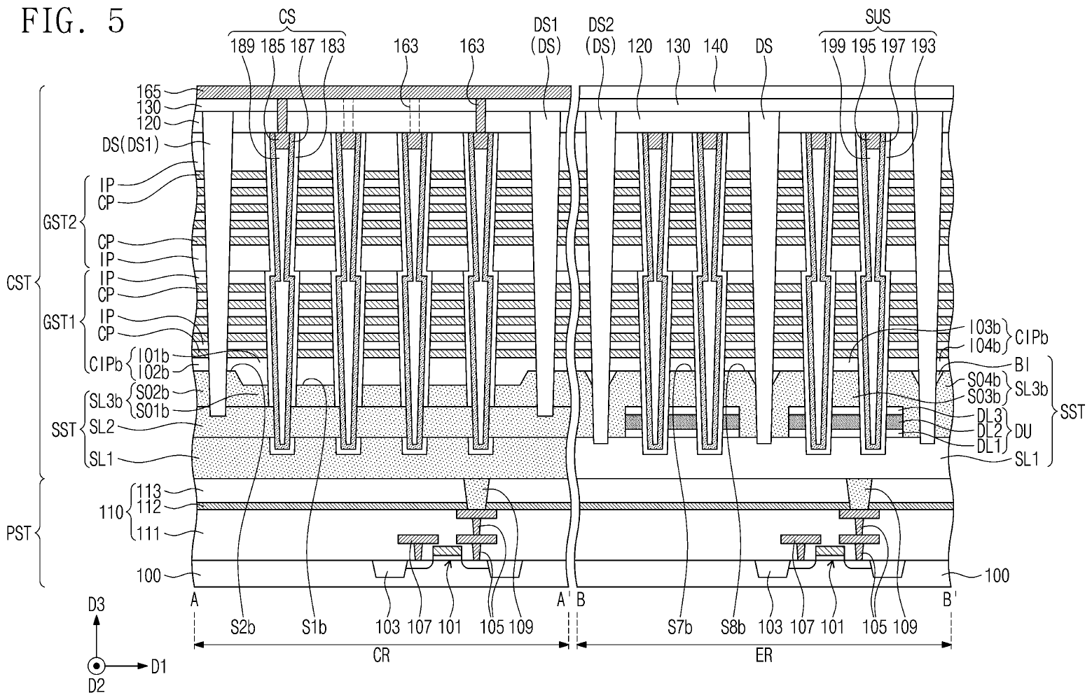

FIG. 5 illustrates a cross-sectional view showing a semiconductor device according to some embodiments.

Referring to FIG. 5, a support source layer SL3b of a semiconductor device may include a first source part SO1b through which the memory channel structure CS penetrates, a second source part SO2b through which the first separation part DS1 of the separation structure DS penetrates, a third source part SO3b through which the support structure SUS penetrates, and a fourth source part SO4b through which the second separation part DS2 of the separation structure DS penetrates.

A connection dielectric pattern CIPb in contact with the support source layer SL3b may include a first dielectric part IO1b in contact with the first source part SO1b, a second dielectric part IO2b in contact with the second source part SO2b, a third dielectric part IO3b in contact with the third source part SO3b, and a fourth dielectric part IO4b in contact with the fourth source part SO4b.

The first source part SO1b may include a first contact surface S1b in contact with the first dielectric part IO1b. The second source part SO2b may include a second contact surface S2b in contact with the second dielectric part IO2b. The third source part SO3b may include a third contact surface S7b in contact with the third dielectric part IO3b. The fourth source part SO4b may include a fourth contact surface S8b in contact with the fourth dielectric part IO4b.

The first contact surface S1b may be located at a level lower than those of the second contact surface S2b, the third contact surface S7b, and the fourth contact surface S8b. In some embodiments, the second contact surface S2b, the third contact surface S7b, and the fourth contact surface S8b may be located at the same level.

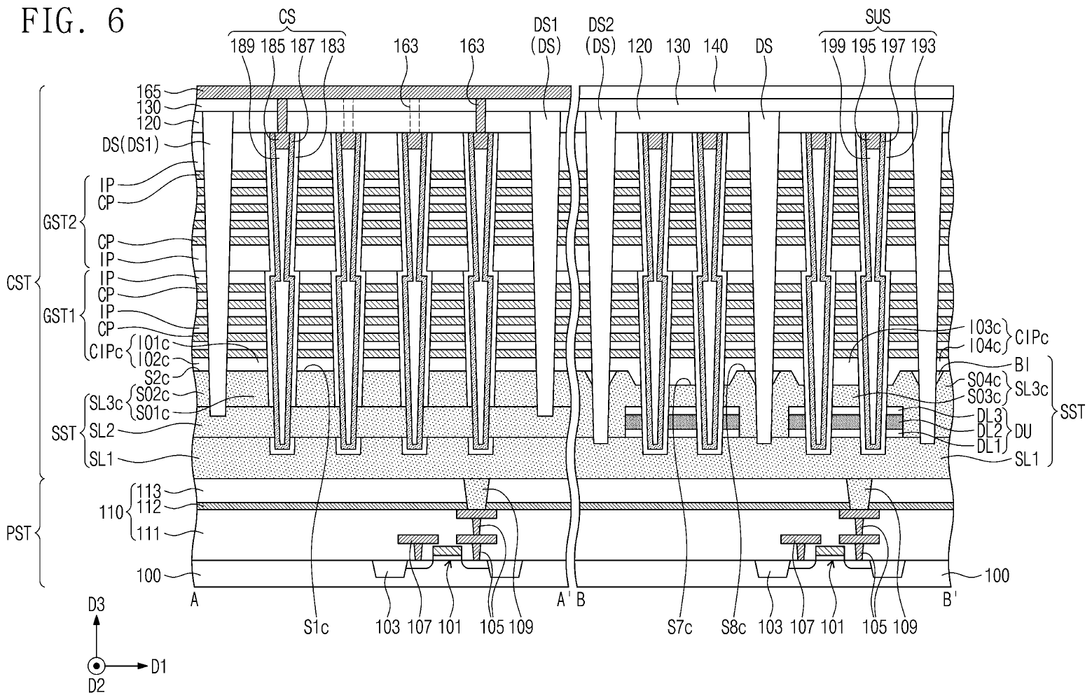

FIG. 6 illustrates a cross-sectional view showing a semiconductor device according to some embodiments.

Referring to FIG. 6, a support source layer SL3c of a semiconductor device may include a first source part SO1c through which the memory channel structure CS penetrates, a second source part SO2c through which the first separation part DS1 of the separation structure DS penetrates, a third source part SO3c through which the support structure SUS penetrates, and a fourth source part SO4c through which the second separation part DS2 of the separation structure DS penetrates.

A connection dielectric pattern CIPc in contact with the support source layer SL3c may include a first dielectric part IO1c in contact with the first source part SO1c, a second dielectric part IO2c in contact with the second source part SO2c, a third dielectric part IO3c in contact with the third source part SO3c, and a fourth dielectric part IO4c in contact with the fourth source part SO4c.

The first source part SO1c may include a first contact surface S1c in contact with the first dielectric part IO1c. The second source part SO2c may include a second contact surface S2c in contact with the second dielectric part IO2c. The third source part SO3c may include a third contact surface S7c in contact with the third dielectric part IO3c. The fourth source part SO4c may include a fourth contact surface S8c in contact with the fourth dielectric part IO4c.

The third contact surface S7c may be located at a level lower than those of the first contact surface S1c, the second contact surface S2c, and the fourth contact surface S8c. In some embodiments, the first contact surface S1c, the second contact surface S2c, and the fourth contact surface S8c may be located at the same level.

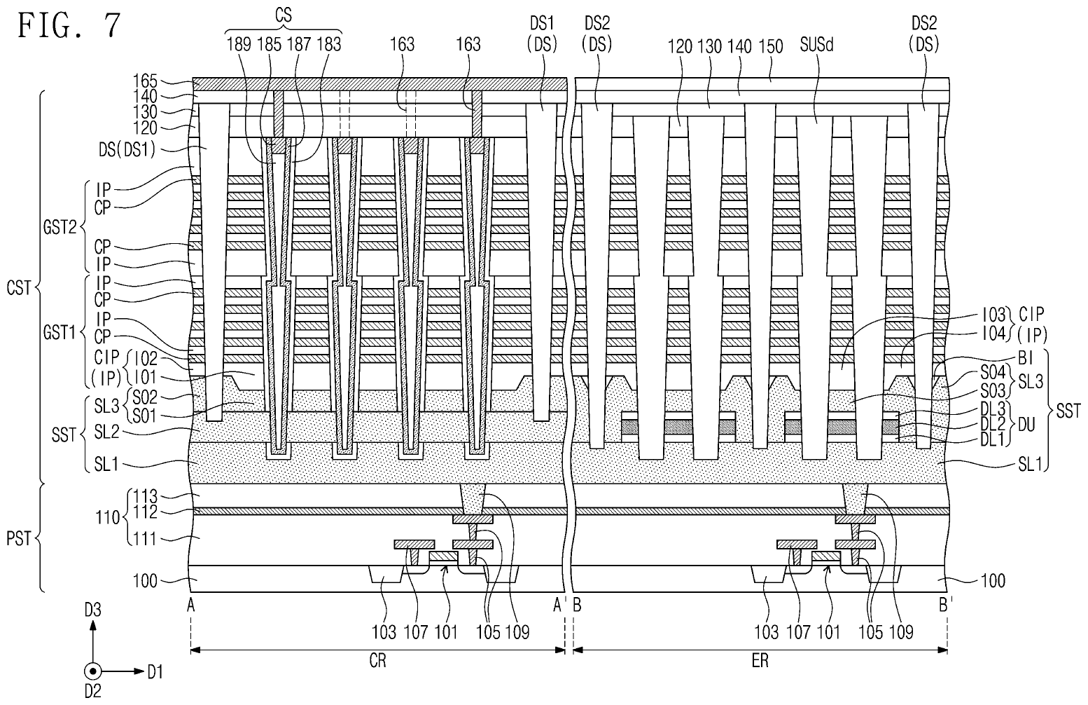

FIG. 7 illustrates a cross-sectional view showing a semiconductor device according to some embodiments.

Referring to FIG. 7, a support structure SUSd of a semiconductor device may have a single unitary structure formed of a dielectric material. For example, the support structure SUSd may be formed of oxide. The support structure SUSd may penetrate through the first gate stack structure GST1, the second gate stack structure GST2, and the first cover dielectric layer 120.

The second cover dielectric layer 130 may be provided on the first cover dielectric layer 120 and the support structures SUSd. The separation structures DS may penetrate through the first gate stack structure GST1, the second gate stack structure GST2, the first cover dielectric layer 120, and the second cover dielectric layer 130. The third cover dielectric layer 140 may be provided on the second cover dielectric layer 130 and the separation structures DS. The bit-line contacts 163 may penetrate through the first, second, and third cover dielectric layers 120, 130, and 140. A fourth cover dielectric layer 150 may be provided on the third cover dielectric layer 140 and the bit-line contacts 163. The fourth cover dielectric layer 150 may include a dielectric material. The bit lines 165 may be provided in the fourth cover dielectric layer 150.

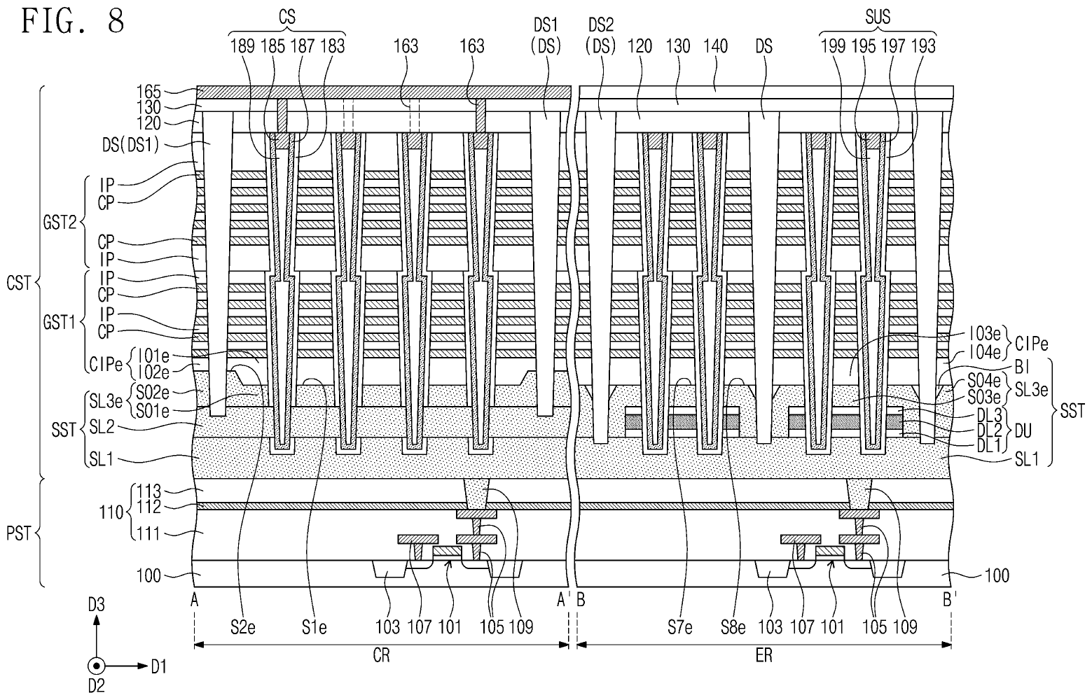

FIG. 8 illustrates a cross-sectional view showing a semiconductor device according to some embodiments.

Referring to FIG. 8, a support source layer SL3e of a semiconductor device may include a first source part SO1e through which the memory channel structure CS penetrates, a second source part SO2e through which the first separation part DS1 of the separation structure DS penetrates, a third source part SO3e through which the support structure SUS penetrates, and a fourth source part SO4e through which the second separation part DS2 of the separation structure DS penetrates.

A connection dielectric pattern CIPe in contact with the support source layer SL3e may include a first dielectric part IO1e in contact with the first source part SO1e, a second dielectric part IO2e in contact with the second source part SO2e, a third dielectric part IO3e in contact with the third source part SO3e, and a fourth dielectric part IO4e in contact with the fourth source part SO4e.

The first source part SO1e may include a first contact surface S1e in contact with the first dielectric part TO1e. The second source part SO2e may include a second contact surface S2e in contact with the second dielectric part IO2e. The third source part SO3e may include a third contact surface S7e in contact with the third dielectric part IO3e. The fourth source part SO4e may include a fourth contact surface S8e in contact with the fourth dielectric part IO4e.

The second contact surface S2e may be located at a level higher than those of the first contact surface S1e, the third contact surface S7e, and the fourth contact surface S8e. In some embodiments, the first contact surface S1e, the third contact surface S7e, and the fourth contact surface S8e may be located at the same level.

In a semiconductor device and an electronic system including the same according to some embodiments of the present inventive concepts, a source structure may include portions whose thicknesses are different from each other, and thus it may be possible to improve a process margin for forming a memory channel structure, a support structure, and a separation structure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Spatially descriptive terms, such as, but not limited to, “above,” “below,” “upper,” “bottom” and “lower,” may be used herein to indicate a position of elements, structures or features relative to one another as illustrated in the figures, rather than an absolute position. Thus, the semiconductor device may be otherwise oriented (e.g., rotated 90 degrees or at other orientations), and the spatially relative descriptions used herein may be interpreted accordingly.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. Likewise, it should be appreciated that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Although the present invention has been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive. Moreover, the embodiments discussed above may be combined with each other if necessary.

What is claimed is:

1. A semiconductor device, comprising:
a source structure that includes a support source layer;
a gate stack structure on the support source layer;
a memory channel structure that penetrates through the gate stack structure and at least a portion of the support source layer; and
a separation structure that penetrates through the gate stack structure and at least a portion of the support source layer,
wherein the support source layer includes:
a first source part through which the memory channel structure penetrates; and
a second source part through which the separation structure penetrates,
wherein a top surface of the first source part is farther than a top surface of the second source part from the gate stack structure.

2. The semiconductor device of claim 1, wherein a cross-sectional thickness of the first source part is less than a cross-sectional thickness of the second source part.

3. The semiconductor device of claim 1, wherein the gate stack structure includes a connection dielectric pattern in contact with the support source layer,
wherein the connection dielectric pattern includes:
a first dielectric part through which the memory channel structure penetrates; and
a second dielectric part through which the separation structure penetrates,
wherein a bottom surface of the first dielectric part farther than a bottom surface of the second dielectric part from the gate stack structure.

4. The semiconductor device of claim 3, wherein a cross-sectional thickness of the first dielectric part is greater than a cross-sectional thickness of the second dielectric part.

5. The semiconductor device of claim 1, further comprising a support structure that penetrates through the gate stack structure and at least a portion of the support source layer,
wherein the support source layer further includes a third source part through which the support structure penetrates, and
wherein a top surface of the third source part is farther than the top surface of the second source part from the gate stack structure.

6. The semiconductor device of claim 5, wherein the separation structure includes:
a first separation part adjacent to the memory channel structure; and
a second separation part adjacent to the support structure,
wherein the first separation part penetrates through the second source part,
wherein the support source layer further includes a fourth source part through which the second separation part penetrates, and
wherein a top surface of the fourth source part is closer than the top surface of the first source part and the top surface of the third source part to the gate stack structure.

7. The semiconductor device of claim 1, wherein the support source layer includes a connection surface that connects the top surface of the first source part to the top surface of the second source part,
wherein the connection surface is inclined.

8. The semiconductor device of claim 7, wherein the connection surface has a level that rises in a direction from the top surface of the first source part to the top surface of the second source part.

9. The semiconductor device of claim 1, wherein the source structure further includes:
a base source layer; and
an intervening source layer between the base source layer and the support source layer,
wherein the intervening source layer is electrically connected to the memory channel structure.

10. A semiconductor device, comprising:
a source structure that includes a support source layer;
a gate stack structure that includes a connection dielectric pattern in contact with the support source layer;
a memory channel structure that penetrates through the gate stack structure and at least a portion of the support source layer; and
a separation structure that penetrates through the gate stack structure and at least a portion of the support source layer,
wherein the support source layer includes:
a first source part through which the memory channel structure penetrates; and
a second source part through which the separation structure penetrates,
wherein the connection dielectric pattern includes:
a first dielectric part through which the memory channel structure penetrates; and
a second dielectric part through which the separation structure penetrates,
wherein the first source part includes a first contact surface in contact with the first dielectric part,
wherein the second source part includes a second contact surface in contact with the second dielectric part, and
wherein a level of the first contact surface is different from a level of the second contact surface.

11. The semiconductor device of claim 10, wherein the support source layer includes a connection surface that connects the first contact surface to the second contact surface,
wherein the connection surface is orthogonal to the first contact surface and the second contact surface.

12. The semiconductor device of claim 10, further comprising a support structure that penetrates through the gate stack structure and the support source layer,
wherein the support source layer further includes a third source part through which the support structure penetrates,
wherein the connection dielectric pattern further includes a third dielectric part through which the support structure penetrates, and
wherein the third source part includes a third contact surface in contact with the third dielectric part.

13. The semiconductor device of claim 12, wherein a level of the third contact surface is different from the level of the second contact surface.

14. The semiconductor device of claim 13, wherein the level of the third contact surface is the same as the level of the first contact surface.

15. The semiconductor device of claim 12, wherein a level of the third contact surface is different from the level of the first contact surface.

16. The semiconductor device of claim 15, wherein the level of the third contact surface is the same as the level of the second contact surface.

17. The semiconductor device of claim 10, wherein a thickness of the first source part is less than a thickness of the first dielectric part.

18. The semiconductor device of claim 17, wherein a thickness of the second source part is greater than a thickness of the second dielectric part.

19. An electronic system, comprising:
a main board;
a semiconductor device on the main board; and
a controller on the main board and electrically connected to the semiconductor device,
wherein the semiconductor device includes:
a source structure that includes a support source layer;
a gate stack structure that includes a connection dielectric pattern in contact with the support source layer;
a memory channel structure that penetrates through the gate stack structure and at least a portion of the support source layer; and
a separation structure that penetrates through the gate stack structure and at least a portion of the support source layer,
wherein the support source layer includes:
a first source part through which the memory channel structure penetrates; and
a second source part through which the separation structure penetrates,
wherein the connection dielectric pattern includes:
a first dielectric part in contact with the first source part; and
a second dielectric part in contact with the second source part,
wherein a thickness of the first source part is less than a thickness of the second source part, and
wherein a thickness of the first dielectric part is greater than a thickness of the second dielectric part.

20. The electronic system of claim 19, wherein a top surface of the first source part is farther than a top surface of the second source part from the gate stack structure.
